(19) United States
(12) Patent Application Publication
(10) Pub. No.: US 2024/0426746 A1
(43) Pub. Date: Dec. 26, 2024

(54) HEAT TREATMENT APPARATUS AND ACCURATE TEMPERATURE MEASUREMENT METHOD FOR SEMICONDUCTOR WORKPIECE

(71) Applicant: Beijing E-Town Semiconductor Technology Co., Ltd., Beijing (CN)

(72) Inventors: Wenyan WANG, Beijing (CN); Jianmin JI, Beijing (CN); Wenyi LI, Beijing (CN)

(21) Appl. No.: 18/731,662

(22) Filed: Jun. 3, 2024

(30) Foreign Application Priority Data
Jun. 26, 2023 (CN) 202310762006.1

(51) Int. Cl. G01N 21/3563; G01N 21/55; H05B 3/00

(52) U.S. Cl. CPC G01N 21/3563; G01N 21/55; G01N 2021/3568; G01N 2021/558; H05B 3/0047

(57) ABSTRACT

A heat treatment apparatus is provided, which includes: a reaction chamber defined by an upper cover plate, a lower cover plate and a reaction chamber body; an infrared emitter located at an end of the upper cover plate; an infrared reflection sensor located at another end of the upper cover plate, and an infrared transmission sensor located at another end of the lower cover plate. The infrared emitter and the infrared reflection sensor are located at a side of the upper cover plate facing to the reaction chamber, the infrared transmission sensor is located at a side of the lower cover plate facing to the reaction chamber, the infrared emitter is located on a sidewall of an end of the reaction chamber body, and the infrared reflection sensor and the infrared transmission sensor are located on a sidewall of another end of the reaction chamber body.

### CROSS-REFERENCE TO RELATED APPLICATIONS

The present application claims priority to Chinese Patent Application No. CN202310762006.1, filed with the China National Intellectual Property Administration on Jun. 26, 2023, the disclosure of which is hereby incorporated herein by reference in its entirety.

### TECHNICAL FIELD

The present disclosure relates to the field of semiconductor processing technology, in particular, to the field of heat treatment of semiconductor workpieces.

### BACKGROUND

Heating temperature required for a semiconductor workpiece in a heat treatment process is usually around 400° C. to 1200° C. In a rapid heat treatment process, a lamp array is usually used to perform heat treatment on the semiconductor workpiece in a double-sided heating method. Reliable and accurate measurement of temperature of the workpiece is crucial in the heat treatment process.

### SUMMARY

The present disclosure provides a heat treatment apparatus and an accurate measurement method for a semiconductor workpiece.

According to an aspect of the present disclosure, a heat treatment apparatus for a semiconductor workpiece is provided, which includes:
one or more heating elements configured to heat the semiconductor workpiece;
an upper cover plate and a lower cover plate;
a reaction chamber defined by the upper cover plate, the lower cover plate and a reaction chamber body;
a workpiece support element configured to support the semiconductor workpiece;
at least one infrared emitter located at a first end of the upper cover plate; and
at least one infrared reflection sensor located at a second end of the upper cover plate, and at least one infrared transmission sensor located at a second end of the lower cover plate, the second ends are opposite to the first end,
where the at least one infrared emitter and the at least one infrared reflection sensor are located at a side of the upper cover plate facing to the reaction chamber respectively, and the at least one infrared transmission sensor is located at a side of the lower cover plate facing to the reaction chamber, and
the at least one infrared emitter is located on a sidewall of a first end of the reaction chamber body, and the at least one infrared reflection sensor and the at least one infrared transmission sensor are located on a sidewall of a second end of the reaction chamber body.

According to another aspect of the present disclosure, an accurate measurement method for a semiconductor workpiece is provided, which includes:
placing the semiconductor workpiece on a workpiece support element in a reaction chamber of a heat treatment apparatus;
disposing an upper cover plate and a lower cover plate;
emitting, by at least one infrared emitter, infrared radiation to the semiconductor workpiece at a side of the upper plate facing to the reaction chamber;
receiving and measuring, by at least one infrared reflection sensor, a first portion infrared radiation amount reflected by a surface of the semiconductor workpiece respectively, and receiving and measuring, by at least one infrared transmission sensor, a second portion infrared radiation amount that is transmitted respectively;
determining reflectivity and transmissivity of the semiconductor workpiece at a site according to the first portion infrared radiation amount and the second portion infrared radiation amount at the same site, and calculating emissivity of the semiconductor workpiece by the reflectivity and the transmissivity; and
calculating temperature on the surface of the semiconductor workpiece at the same site according to the emissivity.

It should be understood that contents described in this part is not intended to identify key or important features of the embodiments of the present disclosure, nor is it intended to limit the scope of the present disclosure. The other features of the present disclosure are made easy to understand by the following description.

### BRIEF DESCRIPTION OF THE DRAWINGS

The accompanying drawings are provided for a better understanding of the present scheme and do not constitute a limitation of the present disclosure.

FIG. 1 is a top view of a heat treatment apparatus according to an embodiment of the present disclosure;

FIG. 2 is a cross-section view of a heat treatment apparatus according to an embodiment of the present disclosure;

FIG. 3 is a schematic diagram of a lamp group partition in a heat treatment apparatus according to an embodiment of the present disclosure; and

FIG. 4 is a schematic diagram of positions of an infrared emitter, an infrared reflection sensor and an infrared transmission sensor in a heat treatment apparatus according to an embodiment of the present disclosure.

### DETAILED DESCRIPTION

Hereinafter, explanation of exemplary embodiments of the present disclosure will be made in conjunction with the accompanying drawings, which includes various details of the embodiments of the present disclosure to facilitate understanding and should be considered merely exemplary. Therefore, those having ordinary skill in the art should recognize that various changes and modifications may be made to the embodiments described herein without departing from the scope of the present disclosure. Similarly, for clarity and conciseness, descriptions of well-known functions and structures are omitted in the following descriptions.

A heat treatment process for a semiconductor workpiece described in the present disclosure may be, for example, a rapid thermal annealing process. Due to different light absorption coefficients of different materials (such as Si, SiO₂, SiN and the like) on the semiconductor workpiece, for example, a wafer, when heating a front side of the semiconductor workpiece by using a single-sided radiation method, a pattern effect will be generated. Therefore, a double-sided heating manner is usually used to reduce uneven heating of temperature of the wafer caused by the pattern effect.

On the other hand, in the rapid thermal annealing process, a non-contact temperature measuring method is used to measure temperature of the semiconductor workpiece. Setting of heating elements (such as lamp groups) for double-sided heating of the wafer allows the semiconductor workpiece to be completely covered by radiation of the heating elements. However, measurement of the temperature of the semiconductor workpiece by the non-contact temperature measuring method will be interfered by light emitted by the heating elements and reflected and transmitted through the semiconductor workpiece, this effect is particularly significant when emissivity of the wafer is low.

The semiconductor workpiece is usually transparent in an infrared band at normal workpiece temperature and does not emit significant blackbody radiation. Conventional radiation measurement methods pose difficulties in the measurement of the temperature of the semiconductor workpiece at temperature below 750° C. due to a large error in measurable blackbody radiation emitted by the workpiece.

According to an aspect of the present disclosure, a heat treatment apparatus for the semiconductor workpiece is provided, which includes:
one or more heating elements configured to heat the semiconductor workpiece;
an upper cover plate and a lower cover plate;
a reaction chamber defined by the upper cover plate, the lower cover plate and a reaction chamber body;
a workpiece support element configured to support the semiconductor workpiece;
at least one infrared emitter located at a first end of the upper cover plate;
at least one infrared reflection sensor located at a second end of the upper cover plate, and at least one infrared transmission sensor located at a second end of the lower cover plate, the second ends are opposite to the first end;
where the at least one infrared emitter and the at least one infrared reflection sensor are located at a side of the upper cover plate facing to the reaction chamber respectively, and the at least one infrared transmission sensor is located at a side of the lower cover plate facing to the reaction chamber, and
the at least one infrared emitter is located on a sidewall of a first end of the reaction chamber body, and the at least one infrared reflection sensor and the at least one infrared transmission sensor are located on a sidewall of a second end of the reaction chamber body.

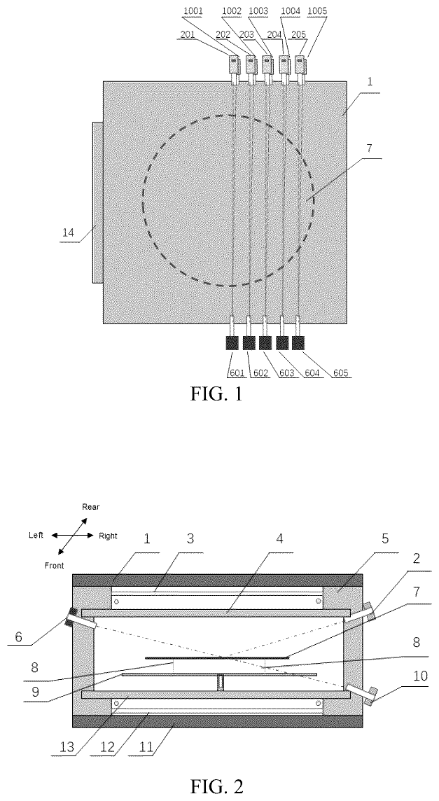

Specifically, referring to FIGS. 1 and 2, the heat treatment apparatus according to an embodiment of the present disclosure includes a top plate 1, a bottom plate 11, an upper heating lamp group 3, a lower heating lamp group 12, an upper cover plate 4, a lower cover plate 13, a reaction chamber body 5, a workpiece support element such as a quartz support plate 9 and a hold needle 8, an infrared emitter 6 and an infrared reflection sensor 2 disposed on two ends of an inner side of the upper cover plate 4, an infrared transmission sensor 10 disposed on an inner side of the lower cover plate, and a reaction chamber door 14.

It may include one or more of each of the above infrared emitter 6, infrared reflection sensor 2 and infrared transmission sensor 10. For example, as shown in FIG. 1, it may respectively include infrared emitters 601, 602, 603, 604 and 605, infrared reflection sensors 201, 202, 203, 204 and 205, and infrared transmission sensors 1001, 1002, 1003, 1004 and 1005.

Specifically, both the upper cover plate and the lower cover plate of the present invention may adopt a high hydroxyl quartz cover plate, so that infrared light having a wavelength of 2.7 μm emitted by the heating lamp groups can be completely filtered out, thereby reducing an impact of radiation from the heating lamp groups on the temperature of the semiconductor workpiece.

The heat treatment apparatus of the present invention is provided with at least one infrared emitter 6, which may emit infrared light having wavelengths of 2.3 μm and/or 2.7 μm to the semiconductor workpiece, at an end of the inner side of the upper cover plate 4 facing to the semiconductor workpiece. According to an implementation, five infrared emitters 601, 602, 603, 604 and 605 may be provided.

Based on the above structure, since the upper cover plate having a hydroxyl quartz material filters out the infrared light having the wavelength of 2.7 μm from the heating lamp groups, the infrared light having a wavelength of 2.7 μm inside the reaction chamber only comes from heat radiation of the infrared emitter and the workpiece, which is more conducive to accurate temperature control for the semiconductor workpiece, especially for measuring the temperature of the semiconductor workpiece under a low emissivity condition of the semiconductor workpiece.

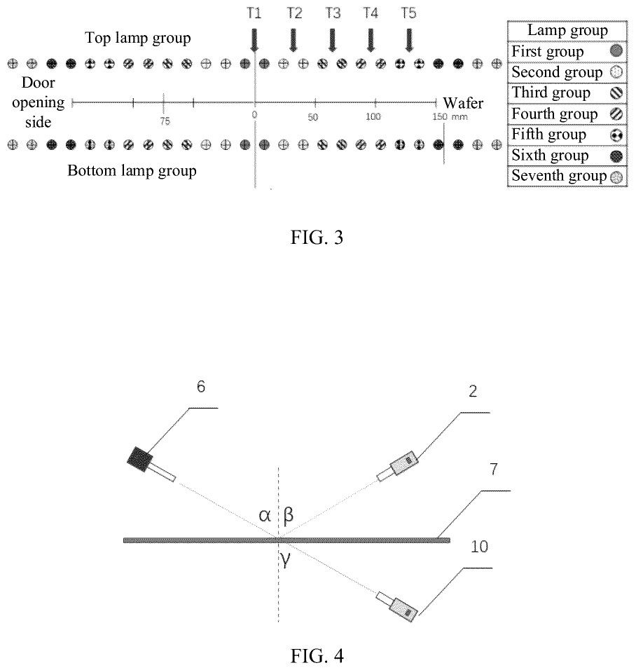

A current heat treatment apparatus uses two temperature measurement points to control configurations of four temperature area controls through program simulation, temperature measurement and controlled areas cannot meet requirements of a more advanced process technology for temperature control of the semiconductor workpiece such as the wafer. Referring to FIGS. 1 and 3, the present invention applies five groups of temperature measurement units (including the infrared emitters, the infrared reflection sensors, and the infrared transmission sensors), which may simulate and control seven temperature areas to heat the wafer by using a program.

Furthermore, as shown in FIG. 3, a top lamp group and a bottom group are divided into seven groups respectively, to divide the reaction chamber between a door opening side and the wafer into two same spaces, and divide an area close to a side of the wafer into five temperature measurement points T1 to T5.

Furthermore, referring to FIG. 4, with respect to a longitudinal axis of the semiconductor workpiece 7 (or a longitudinal axis of the reaction chamber), an angle α of the infrared emitter 6 to the longitudinal axis, an angle β of the infrared reflection sensor 2 to the longitudinal axis and an angle γ of the infrared transmission sensor 10 to the longitudinal axis are 30° to 60° respectively, for example, 45°. Where the infrared emitter 6 and the infrared transmission sensor 10 are located at a same straight line.

The above infrared emitter, infrared reflection sensor and infrared transmission sensor jointly constitute a semiconductor workpiece emissivity measurement system without influence of heating lamps, thereby promoting accurate measurement of the temperature of the semiconductor workpiece, especially accurate measurement of medium temperature between 400° C. and 750° C.

According to another aspect of the present invention, an accurate temperature measurement method for the semiconductor workpiece is provided, which includes steps of:
placing the semiconductor workpiece on the workpiece support element in the reaction chamber of the heat treatment apparatus;
disposing the upper cover plate and the lower cover plate;
emitting, by the at least one infrared emitter, the infrared radiation to the semiconductor workpiece at a side of upper cover plate facing to the semiconductor workpiece;
receiving and measuring, by at least one infrared reflection sensor, a first portion infrared radiation amount reflected by a surface of the semiconductor workpiece respectively, and receiving and measuring, by at least one infrared transmission sensor, a second portion infrared radiation amount that is transmitted respectively;
determining reflectivity and transmissivity of the semiconductor workpiece at a site according to the first portion infrared radiation amount and the second portion infrared radiation amount at the same site, and calculating the emissivity of the semiconductor workpiece by the reflectivity and the transmissivity; and
calculating the temperature on the surface of the semiconductor workpiece at the same site according to the emissivity.

According to an implementation, the accurate temperature measurement method of the present invention includes disposing the upper cover plate 4 and the lower cover plate 14 having the high hydroxyl quartz material, filtering out the infrared light having the wavelength of 2.7 μm emitted by the heating lamp groups; further disposing the infrared emitter 6 having the wavelength of 2.7 μm at the inner side of the upper cover plate having the high hydroxyl quartz material, and radiating the infrared light having the wavelength of 2.7 μm to the wafer 7; and disposing the infrared reflection sensor 2 having the wavelength of 2.7 μm and the infrared transmission sensor 10 having the wavelength of 2.7 μm in a reflection direction and a transmission direction corresponding to the infrared light. The infrared reflection sensor 2 may measure reflectivity of the wafer to the infrared light having the wavelength of 2.7 μm, and the infrared transmission sensor 10 may measure transmissivity of the wafer to the infrared light having the wavelength of 2.7 μm. The infrared emitter 6, the infrared reflection sensor 2 and the infrared transmission sensor 10 together form a wafer emissivity measurement system without an influence of the heating lamp groups, thus temperature of the front side of the wafer may be calculated.

Furthermore, two infrared transmission sensors 10 disposed on a bottom of the reaction chamber and at an outer side of the lower cover plate 13 facing away from the wafer may operate at the wavelength of 2.3 μm for measuring temperature of a back side of the wafer under a low emissivity condition of an amorphous wafer.

Specifically, the infrared light having the wavelength of 2.7 μm emitted by the infrared emitter 6 may be modulated into pulsed light by using a chopper, the pulsed light having the wavelength of 2.7 μm is irradiated on the semiconductor workpiece (wafer) 7, a reflected portion is received by the infrared reflection sensor 2 of 2.7 μm, a transmitted portion is received by the infrared transmission sensor 10 of 2.7 μm. It is calculated that the sum of emissivity, reflectivity and transmissivity of an object is 1 by the following formula (1):

$$ε ( λ ) + ρ ( λ ) + τ ( λ ) = 1 \qquad ( 1 )$$

Real-time reflectivity ρ of the wafer and transmissivity τ of the wafer are determined by the infrared reflection sensor 2 of 2.7 μm and the infrared transmission sensor 10 of 2.7 μm, and emissivity ε of the wafer is calculated. The reflectivity ρ is a ratio of an intensity of the reflected light detected by the infrared reflection sensor to an intensity of the infrared light emitted by the infrared emitter, and the transmissivity τ is a ratio of an intensity of the transmitted light detected by the infrared transmission sensor to the intensity of the infrared light emitted by the infrared emitter.

Meanwhile, the infrared reflection sensor 2 and infrared transmission sensor 10 mentioned above may also receive infrared light from thermal radiation on upper and lower surfaces of the wafer, and the radiated light may be distinguished from the light emitted by the infrared emitter 6 in terms of frequency. The temperature on the front side and the back side of the wafer is calculated based on the following blackbody radiation formula (2):

$$T = \frac{hc}{λ k} \cdot \frac{1}{ln ( \frac{2 π {hc}^{2} Δ λ}{{λ}^{5}} \cdot \frac{ε}{{I}_{Wafer}} + 1 )} \qquad ( 2 )$$

Where I_{wafer} is the received infrared thermal radiation of the wafer, h is the Planck constant, c is the speed of light, and k is the Boltzmann constant, A is a radiation wavelength, & is the emissivity of the wafer.

After the wafer enters a rapid heat treatment chamber and begins being heated, the infrared emitter 6 of 2.7 μm, the infrared reflection sensor 2 of 2.7 μm and the infrared transmission sensor 9 of 2.7 μm continuously measure the reflectivity, the emissivity and the transmissivity of the wafer. A temperature test result obtained from this test may provide a reference temperature within a temperature range of 250-400° C. of the wafer, and a temperature rise state of the wafer may be monitored in real time. When process temperature is between 400-750° C., the infrared transmitter 6 of 2.7 μm, the infrared reflection sensor 2 of 2.7 μm and the infrared transmission sensor 9 of 2.7 μm may accurately calculate the temperature of the wafer, facilitating closed-loop control of the temperature of the wafer. When wafer process temperature is above 750° C., the above infrared transmitter 6 of 2.7 μm, infrared reflection sensor 2 of 2.7 μm and infrared transmission sensor of 2.7 μm may use a traditional method to measure the temperature of the wafer.

According to the above method of the present invention, stability of temperature measurement and control of the heat treatment apparatus may be improved under conditions such as low emissivity (<0.3) of the semiconductor workpiece, sudden change in the emissivity of semiconductor workpiece (such as a polycrystalline silicon layer on the wafer undergoes phase transition during being heated). Meanwhile, a measurement range of the semiconductor workpiece temperature may be extended as low as 250° C.

Preferably, accurately measurable temperature of the aforementioned semiconductor workpiece is within the range of 400-750° C.

Referring to FIG. 3, the heat treatment apparatus of the present invention includes two heating lamp arrays, namely a top lamp group and a bottom lamp group. Each heating lamp array is divided into four groups (indicated by light to dark in gray color). Meanwhile, the reaction chamber is symmetrically divided into two parts from the door opening side to the wafer, and an area between a center and the wafer is divided into five temperature measurement areas T1-T5.

For example, according to the method of the present invention, a plurality of infrared emitters may be provided, and a plurality of infrared reflection sensors and a plurality of infrared transmission sensors may be provided at the same time, thereby increasing temperature measurement sites, expanding a temperature range of testing, and improving temperature testing accuracy. Based on measured temperature at different sites of the semiconductor workpiece, a corresponding lamp group at a site may be independently controlled to achieve accurate temperature control, resulting in a temperature control deviation within +1° C.

It should be understood that various forms of processes shown above may be used to reorder, add, or delete steps. For example, the steps recorded in the present disclosure may be executed in parallel, sequentially, or in different orders, as long as the expected results of the technical solution disclosed by the present disclosure may be achieved, which is not limited herein.

The above specific implementations do not constitute a limitation on the protection scope of the present disclosure. Those having ordinary skill in the art should understand that various modifications, combinations, sub combinations, and substitutions may be made based on design requirements and other factors. Any modifications, equivalent substitutions, and improvements made within the principle of the present disclosure should be included within the protection scope of the present disclosure.

What is claimed is:

1. A heat treatment apparatus for a semiconductor workpiece, comprising:
one or more heating elements configured to heat the semiconductor workpiece;
an upper cover plate and a lower cover plate;
a reaction chamber defined by the upper cover plate, the lower cover plate and a reaction chamber body;
a workpiece support element configured to support the semiconductor workpiece;
at least one infrared emitter located at a first end of the upper cover plate; and
at least one infrared reflection sensor located at a second end of the upper cover plate, and at least one infrared transmission sensor located at a second end of the lower cover plate, the second ends are opposite to the first end,
wherein the at least one infrared emitter and the at least one infrared reflection sensor are located at a side of the upper cover plate facing to the reaction chamber respectively, and the at least one infrared transmission sensor is located at a side of the lower cover plate facing to the reaction chamber, and
the at least one infrared emitter is located on a sidewall of a first end of the reaction chamber body, and the at least one infrared reflection sensor and the at least one infrared transmission sensor are located on a sidewall of a second end of the reaction chamber body.

2. The heat treatment apparatus of claim 1, wherein the at least one infrared emitter emits infrared radiation having one or two wavelengths of 2.3 microns and 2.7 microns.

3. The heat treatment apparatus of claim 1, wherein the at least one infrared emitter, the at least one infrared reflection sensor and the at least one infrared transmission sensor have same quantity.

4. The heat treatment apparatus of claim 2, wherein the at least one infrared emitter, the at least one infrared reflection sensor and the at least one infrared transmission sensor have same quantity.

5. The heat treatment apparatus of claim 1, wherein the infrared emitter is located at a same straight line as a corresponding infrared transmission sensor.

6. The heat treatment apparatus of claim 2, wherein the infrared emitter is located at a same straight line as a corresponding infrared transmission sensor.

7. The heat treatment apparatus of claim 1, wherein the upper cover plate and the lower cover plate are high hydroxyl quartz cover plates, respectively.

8. The heat treatment apparatus of claim 2, wherein the upper cover plate and the lower cover plate are high hydroxyl quartz cover plates, respectively.

9. The heat treatment apparatus of claim 1, wherein an angle between the infrared emitter and a longitudinal axis of the reaction chamber body, an angle between the infrared reflection sensor and the longitudinal axis of the reaction chamber body and an angle between the infrared transmission sensor and the longitudinal axis of the reaction chamber body are same, preferably between 30° to 60°, and most preferably 45°.

10. The heat treatment apparatus of claim 2, wherein an angle between the infrared emitter and a longitudinal axis of the reaction chamber body, an angle between the infrared reflection sensor and the longitudinal axis of the reaction chamber body and an angle between the infrared transmission sensor and the longitudinal axis of the reaction chamber body are same, preferably between 30° to 60°, and most preferably 45°.

11. The heat treatment apparatus of claim 1, wherein the heat treatment apparatus is capable of accurately measure temperature of the semiconductor workpiece within a range of 400-750° C.

12. The heat treatment apparatus of claim 2, wherein the heat treatment apparatus is capable of accurately measure temperature of the semiconductor workpiece within a range of 400-750° C.

13. An accurate measurement method for a semiconductor workpiece, comprising:
placing the semiconductor workpiece on a workpiece support element in a reaction chamber of a heat treatment apparatus;
disposing an upper cover plate and a lower cover plate;
emitting, by at least one infrared emitter, infrared radiation to the semiconductor workpiece at a side of the upper plate facing to the reaction chamber;
receiving and measuring, by at least one infrared reflection sensor, a first portion infrared radiation amount reflected by a surface of the semiconductor workpiece respectively, and receiving and measuring, by at least one infrared transmission sensor, a second portion infrared radiation amount that is transmitted respectively;
determining reflectivity and transmissivity of the semiconductor workpiece at a site according to the first portion infrared radiation amount and the second portion infrared radiation amount at the same site, and calculating emissivity of the semiconductor workpiece by the reflectivity and the transmissivity; and
calculating temperature on the surface of the semiconductor workpiece at the same site according to the emissivity.

14. The accurate measurement method of claim 13, wherein the temperature of the semiconductor workpiece is in a range of 400° C.-750° C.
